(19) United States
(12) Patent Application Publication
(10) Pub. No.: US 2025/0006509 A1
(43) Pub. Date: Jan. 2, 2025

(54) ENCAPSULATION SUBSTRATE AND MANUFACTURING METHOD THEREOF, AND FUNCTIONAL SUBSTRATE AND MANUFACTURING METHOD THEREOF

(71) Applicants: Beijing BOE Optoelectronics Technology Co., Ltd., Beijing (CN); BOE TECHNOLOGY GROUP CO., LTD., Beijing (CN)

(72) Inventors: Jingshu ZHANG, Beijing (CN); Yifan WU, Beijing (CN); Shuai XU, Beijing (CN); Yue LI, Beijing (CN); Yuelei XIAO, Beijing (CN); Bin ZHAO, Beijing (CN); Kidong HAN, Beijing (CN); Yulin FENG, Beijing (CN); Qichang AN, Beijing (CN); Zijian WANG, Beijing (CN)

(21) Appl. No.: 18/580,096

(22) PCT Filed: Aug. 26, 2022
(86) PCT No.: PCT/CN2022/115096

§ 371 Date: Jan. 17, 2024

(51) Int. Cl. H01L 21/48; H01L 21/56; H01L 23/00; H01L 23/31; H01L 23/498

(52) U.S. Cl. CPC H01L 21/486; H01L 21/568; H01L 23/3121; H01L 23/49827; H01L 23/49838; H01L 24/16; H01L 2224/16227

(57) ABSTRACT

An encapsulation substrate and a manufacturing method therefor, and a functional substrate and a manufacturing method therefor are provided. The method for manufacturing an encapsulation substrate includes providing an initial substrate having first and second surfaces oppositely arranged along a thickness direction thereof; processing the initial substrate to form a blind hole extending through a part of the initial substrate in the thickness direction; forming a first connection electrode in the blind hole, and forming a first signal trace on the first surface; thinning the initial substrate from a side of the second surface to form a dielectric substrate and expose the first connection electrode; forming a second signal trace on a side of the dielectric substrate away from the first signal trace such that one of the first and second signal traces is electrically connected to the chip; the other one is electrically connected to the printed circuit board.

### TECHNICAL FIELD

The present disclosure relates to the field of encapsulation technology, and in particular to an encapsulation substrate and a method for manufacturing an encapsulation substrate, and a functional substrate and a method for manufacturing a functional substrate.

### BACKGROUND

The encapsulation technology plays a supporting role in the development of semiconductor technology. The semiconductor encapsulation technology is a method, structure, and process for encapsulating a semiconductor (integrated circuit) chip in a standard component. With the continuous development of the encapsulation technology, the encapsulation technology gradually develops from a two-dimensional encapsulation to a three-dimensional encapsulation since the 21st century, a substrate is an important component of the three-dimensional modular encapsulation, mainly used for supporting a chip and has functions such as a structural support, a signal transmission, a pin size enlargement, a heat dissipation enhancement and the like. A vertical interconnection technology based on through holes in the substrate is the research focus of advanced three-dimensional encapsulation. At present, a commonly commercial encapsulation substrate mainly includes an organic substrate, a ceramic substrate, a metal substrate and a composite substrate, with common problems that fine vias cannot be formed in the organic substrate, the metal substrate cannot be applied to the field of high-frequency signal transmission due to high radio frequency loss, the ceramic substrate, as a potential encapsulation substrate, has the problems of insufficient fine wiring, high processing cost and the like, and the composite substrate generally applied at present has high cost and high technical difficulty, and is in a monopoly position in the industry, which is not beneficial to further market expansion.

With the rapid development of glass processing technology, a glass-based device begins to emerge in the field of microelectronic manufacture, and glass, as a material of the substrate for encapsulation, has many inherent advantages: good insulation, low dielectric loss, excellent surface flatness, low material cost, high chemical stability, good matching of coefficient of thermal expansion (CTE) with chips and printed circuit boards, and the like, and is a material of the substrate which is highly thought of at present in the industry. However, the greatest problem is that the glass is a brittle material. Particularly, the glass is thinned to be less than hundred micrometers, so that there is a risk that the glass is smashed in warm pressing processes, such as reflow soldering, molding and the like, in the chip encapsulation process when the glass is directly used as the encapsulation substrate.

### SUMMARY

The present disclosure is directed to at least one of the technical problems in the prior art, and provides an encapsulation substrate and a method for manufacturing an encapsulation substrate, and a functional substrate and a method for manufacturing a functional substrate.

The embodiment of the present disclosure provides a method for manufacturing an encapsulation substrate, including: providing an initial substrate such that the initial substrate includes a first surface and a second surface which are oppositely arranged along a thickness direction of the initial substrate and the initial substrate includes a glass substrate; processing the initial substrate to form a blind hole extending through a part of the initial substrate in the thickness direction of the initial substrate such that a first opening of the blind hole extends through the first surface; forming a first connection electrode in the blind hole, and forming a first signal trace on the first surface such that one end of the first signal trace is electrically connected to the first connection electrode; thinning the initial substrate from a side of the second surface to form a dielectric substrate including a through hole and to expose the first connection electrode; and forming a second signal trace on a side of the dielectric substrate away from the first signal trace such that one of the first signal trace and the second signal trace is configured to be electrically connected to a chip, and the other one is configured to be electrically connected to a printed circuit board.

In some embodiments of the present disclosure, the thinning the initial substrate from the side of the second surface to form the dielectric substrate comprising the through hole and to expose the first connection electrode includes: fixing a carrier substrate on a side of the first signal trace away from the first surface; and thinning the initial substrate from the side of the second surface to form the dielectric substrate comprising the through hole and to expose the first connection electrode; before the forming the second signal trace on the side of the dielectric substrate away from the first signal trace, the method further includes: removing the carrier substrate.

In some embodiments of the present disclosure, after the forming the second signal trace on the side of the dielectric substrate away from the first signal trace, the method further includes: fixing an auxiliary substrate on a side of the second signal trace away from the dielectric substrate; mounting the chip on a side of the first signal trace away from the dielectric substrate, wherein the chip is electrically connected to the first signal trace; forming an encapsulation layer on a side of the chip away from the dielectric substrate; and removing the auxiliary substrate.

In some embodiments of the present disclosure, the chip is electrically connected to the first signal trace by soldering.

In some embodiments of the present disclosure, the auxiliary substrate is fixed to the side of the second signal trace away from the dielectric substrate through a first adhesive layer.

In some embodiments of the present disclosure, the carrier substrate is fixed to the side of the first signal trace away from the first surface through a second adhesive layer.

In some embodiments of the present disclosure, before the thinning the initial substrate from the side of the second surface to form the dielectric substrate comprising the through hole and to expose the first connection electrode, the method further includes: mounting the chip on a side of the first signal trace away from the first surface such that the chip is electrically connected to the first signal trace.

In some embodiments of the present disclosure, before the thinning the initial substrate from the side of the second surface to form the dielectric substrate comprising the through hole and to expose the first connection electrode, the method further includes: fixing an auxiliary substrate on a side of the first signal trace away from the first surface; and thinning the initial substrate from the side of the second surface to form the dielectric substrate comprising the through hole and to expose the first connection electrode; after the forming the second signal trace on the side of the dielectric substrate away from the first signal trace, the method further includes: mounting the chip on a side of the second signal trace away from the dielectric substrate such that the chip is electrically connected to the second signal trace; and removing the auxiliary substrate.

In some embodiments of the present disclosure, the auxiliary substrate is fixed to a side of the first signal trace away from the first surface through a first adhesive layer.

In some embodiments of the present disclosure, one end of the first signal trace is connected to the first connection electrode, and a first connection pad is formed on a side of the other end of the first signal trace away from the dielectric substrate; and one end of the second signal trace is connected to the first connection electrode, and a second connection pad is formed on a side of the other end of the second signal trace away from the dielectric substrate.

In some embodiments of the present disclosure, the first connection electrode is formed through an electroplating process or an electroless plating process.

Embodiments of the present disclosure provide an encapsulation substrate, including: a dielectric substrate including a through hole extending through the dielectric substrate in a thickness direction of the dielectric substrate, the dielectric substrate being a glass substrate; a first connection electrode in the through hole; and a first signal trace and a second signal trace respectively on two opposite surfaces of the dielectric substrate and electrically connected to each other through the first connection electrode; and one of the first signal trace and the second signal trace is configured to be electrically connected to a chip, and the other one is configured to be electrically connected to a printed circuit board.

In some embodiments of the present disclosure, the encapsulation substrate further includes a chip electrically connected to the first signal trace, and an encapsulation layer on a side of the chip away from the dielectric substrate.

In some embodiments of the present disclosure, one end of the first signal trace is electrically connected to the first connection electrode, and the other end of the first signal trace is electrically connected to a first connection pad on a side of the first signal trace away from the dielectric substrate.

In some embodiments of the present disclosure, one end of the second signal trace is electrically connected to the first connection electrode, and the other end of the second signal trace is electrically connected to a second connection pad on a side of the second signal trace away from the dielectric substrate.

Embodiments of the present disclosure provide a method for manufacturing a functional substrate, including the method for manufacturing an encapsulation substrate in any one of the above embodiments.

In some embodiments of the present disclosure, the first signal trace is electrically connected to the chip, the method further includes: electrically connecting the second signal trace with the printed circuit board; or the second signal trace is electrically connected to the chip, the method further includes: electrically connecting the first signal trace with the printed circuit board.

In some embodiments of the present disclosure, the electrically connecting the second signal trace with the printed circuit board includes: electrically connecting the second signal trace with the printed circuit board by soldering.

In some embodiments of the present disclosure, the electrically connecting the first signal trace with the printed circuit board includes: electrically connecting the first signal trace with the printed circuit board by soldering.

Embodiments of the present disclosure provide a functional substrate, which includes the encapsulation substrate in any one of the above embodiments; one of the first signal trace and the second signal trace is electrically connected to the chip, and the other one is electrically connected to the printed circuit board.

### BRIEF DESCRIPTION OF DRAWINGS

FIG. 1 is a schematic diagram of a structure of an encapsulation substrate according to an embodiment of the present disclosure.

FIG. 2 is a schematic diagram of a structure of a functional substrate according to an embodiment of the present disclosure.

FIG. 3 is a flowchart of a method for manufacturing an encapsulation substrate according to a first example of the embodiment of the present disclosure.

FIG. 4 is a flowchart of a method for manufacturing an encapsulation substrate according to a second example of the embodiment of the present disclosure.

FIG. 5 is a flowchart of a method for manufacturing an encapsulation substrate according to a third example of the embodiment of the present disclosure.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

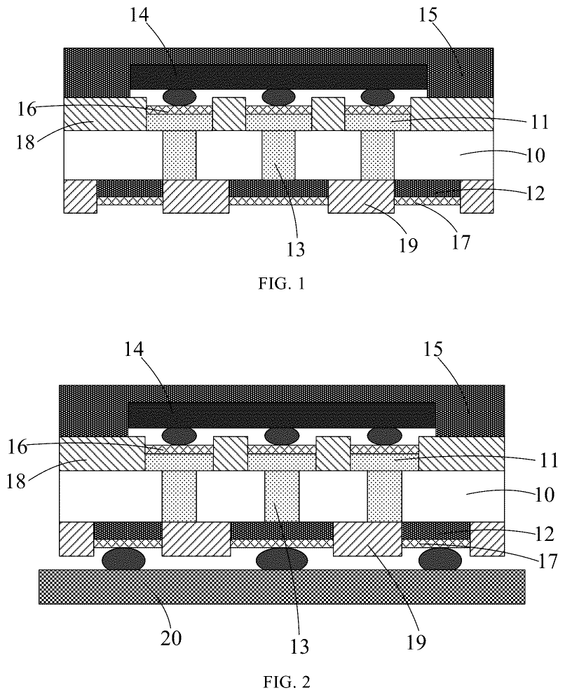

FIG. 1 is a schematic diagram of a structure of an encapsulation substrate according to an embodiment of the present disclosure. As shown in FIG. 1, the encapsulation substrate includes a dielectric substrate 10, a first signal trace 11, a second signal trace 12, a first connection electrode 13, a chip 14, and an encapsulation layer 15. The dielectric substrate 10 is provided with a through hole extending through the dielectric substrate 11 along a thickness direction of the dielectric substrate 11 therein, the first connection electrode 13 is filled in the through hole, the first signal trace 11 and the second signal trace 12 are respectively located on two opposite sides of the dielectric substrate 10 along the thickness direction of the dielectric substrate 11, and the first signal trace 11 and the second signal trace 12 are electrically connected to each other through the first connection electrode 13. The chip 14 is connected to the first signal trace 11, and the encapsulation layer 15 is covered on a side of the chip 14 away from the first signal trace 11. Alternatively, a first insulating layer 18 is further disposed on a side of the first signal trace 11 away from the dielectric substrate 10, and is provided with a first via exposing a position where the first signal trace 11 and the chip 14 are electrically connected to each other. A second insulating layer 19 is further disposed on a side of the second signal trace 12 away from the dielectric substrate 10, and is provided with a second via exposing a position where the second signal trace 12 and a printed circuit board are electrically connected to each other.

The dielectric substrate 10 in the embodiment of the present disclosure is a glass substrate, and the glass substrate has low dielectric loss and thus, has a good application prospect in the field of high-frequency signal transmission.

In some examples, the chip 14 and the first signal trace 11 may be connected together by soldering, so that a first connection pad 16 is formed at one end of the first signal trace 11 electrically connected to the chip 14, and the first connection pad 16 is soldered to the chip 14, thereby electrically connecting the first signal trace 11 to the chip 14. Furthermore, solder balls or copper columns may be used for soldering.

In some examples, a second connection pad 17 may be formed at one end of the second signal trace 12 electrically connected to the printed circuit board 20, and the second connection pad 17 is soldered to the printed circuit board 20, so as to electrically connect the second signal trace 12 to the printed circuit board 20. Furthermore, solder balls or copper columns may be used for soldering.

FIG. 2 is a schematic diagram of a structure of a functional substrate according to an embodiment of the present disclosure. As shown in FIG. 2, the embodiment of the present disclosure provides a functional substrate, which includes the encapsulation substrate and a printed circuit board 20 connected to the second signal trace 12, so as to electrically connect the chip 14 and the printed circuit board 20. The second signal trace 12 and the printed circuit board 20 may be electrically connected together by soldering. In this case, the second connection pad 17 may be formed at one end of the second signal trace 12 electrically connected to the printed circuit board 20, and the second connection pad 17 is soldered to the printed circuit board 20, so as to electrically connect the second signal trace 12 to the printed circuit board 20. Furthermore, solder balls or copper columns may be used for soldering.

The inventors have found that a thickness of the dielectric substrate 10 is reduced in order to achieve the lightweight and thinness of the encapsulation substrate, but when the thickness of the dielectric substrate 10 is reduced to a certain level, there is a risk that the dielectric substrate 10 is smashed during processing.

In view of the above problems, embodiments of the present disclosure provide a method for manufacturing an encapsulation substrate, which can effectively avoid the problem that the dielectric substrate is smashed during processing. The description is given with reference to the embodiments.

The embodiment of the present disclosure provides a method for manufacturing an encapsulation substrate, which includes the following steps S01 to S05.

At the step S01, an initial substrate is provided. The initial substrate includes a first surface and a second surface which are oppositely arranged along a thickness direction of the initial substrate.

In some examples, the initial substrate includes, but is not limited to, a glass substrate. In the embodiment of the present disclosure, as an example, the initial substrate is the glass substrate. The glass substrate has low dielectric loss and thus, has a good application prospect in the field of high-frequency signal transmission.

At the step S02, the initial substrate is processed to form a blind hole extending through a part of the initial substrate in the thickness direction of the initial substrate, and a first opening of the blind hole extends through the first surface.

In some examples, the step S02 may include forming the blind hole extending through a partial thickness of the initial substrate through a mechanical process, a laser process, a chemical etching process, a laser modification process and the like in combination with a wet etching process.

At the step S03, the first connection electrode is formed in the blind hole and a first signal trace is formed on the first surface of the initial substrate such that one end of the first signal trace is electrically connected to the first connection electrode, and a first insulating layer is formed on a side of the first signal trace away from the initial substrate, the first insulating layer is provided with a first via, and the first via exposes one end of the first signal trace connected to the chip.

In some examples, the step S03 may include coating the blind hole and the first surface of the initial substrate with a first conductive thin film, i.e., forming a first seed layer, then performing an electroplating or electroless plating process on the first seed layer, so that the first seed layer is grown and thus becomes thick; forming a first connection electrode in the blind hole, and then patterning (i.e., coating glue, exposing, developing, etching) the grown thick first seed layer on the first surface to form a pattern including the first signal trace; and finally, forming the first insulating layer on a side of the first signal trace away from the initial substrate, and forming the first via extending through the first insulating layer, wherein the first via exposes one end of the first signal trace connected to the chip.

At the step S04, a side where the second surface of the initial substrate is located is thinned to form the dielectric substrate and to expose the first connection electrode.

In some examples, the step S04 may include thinning the side where the second surface of the initial substrate is located, followed by polishing through a CMP process to reduce roughness and expose the first connection electrode. That is, a through hole extending through the dielectric substrate is formed in step S04.

At the step S05, the second signal trace is formed on a side of the dielectric substrate away from the first signal trace such that one end of the second signal trace is electrically connected to the first connection electrode, and a second insulating layer is formed on a side of the second signal trace away from the dielectric substrate such that the second insulating layer is provided with a second via, and the second via exposes one end of the second signal trace connected to the printed circuit board.

In some examples, the step S05 may include forming a second conductive film on a side of the dielectric substrate away from the first signal trace, coating a photoresist on a side of the second conductive thin film away from the dielectric substrate, and then forming a pattern including the second signal trace through exposure, development, and etching processes; and finally, forming a second insulating layer on a side of the second signal trace away from the dielectric substrate, and forming a second via extending through the second insulating layer, wherein the second via exposes one end of the second signal trace connected to the printed circuit board.

It should be noted that one of the first signal trace and the second signal trace is electrically connected to the chip to be subsequently mounted, and the other is electrically connected to the printed circuit board.

A method for manufacturing an encapsulation substrate according to an embodiment of the present disclosure is described below with reference to specific examples.

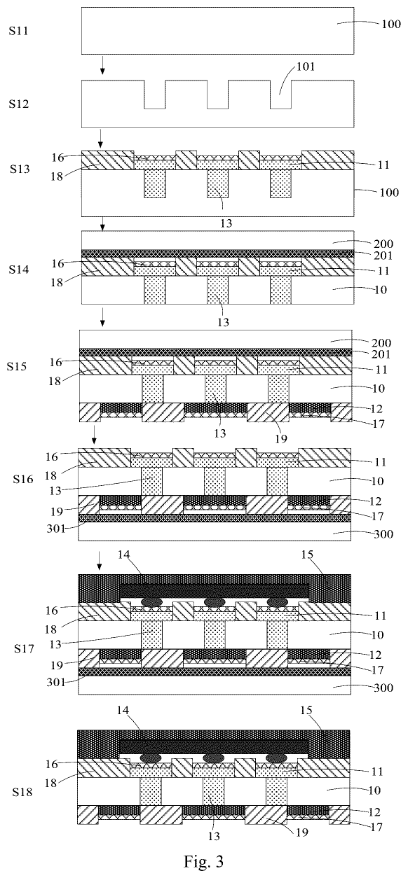

In a first example, FIG. 3 is a flowchart of a method of manufacturing an encapsulation substrate according to a first example of the embodiment of the present disclosure. As shown in FIG. 3, in the encapsulation substrate, the first signal trace 11 is electrically connected to the chip 14, and the second signal trace 12 is electrically connected to the printed circuit board 20. The method for manufacturing an encapsulation substrate specifically includes the following steps S11 to S18.

At the step S11, an initial substrate 100 is provided. The initial substrate 100 includes a first surface and a second surface which are oppositely arranged along a thickness direction of the initial substrate 100.

In some examples, the initial substrate 100 includes, but is not limited to, a glass substrate. In the embodiment of the present disclosure, as an example, the initial substrate 100 is the glass substrate. The glass substrate has low dielectric loss and thus, has a good application prospect in the field of high-frequency signal transmission.

At the step S12, the initial substrate 100 is processed to form a blind hole 101 extending through a part of the initial substrate 100 in the thickness direction of the initial substrate 100, and a first opening of the formed blind hole 101 extends through the first surface.

In some examples, the step S12 may include forming the blind hole extending through the part of the initial substrate 100 by a thickness through a mechanical process, a laser process, a chemical etching process, a laser modification process and the like in combination with a wet etching process.

At the step S13, a first connection electrode 13 is formed in the blind hole 101, a first signal trace 11 is formed on the first surface of the initial substrate 100, and one end of the first signal trace 11 is electrically connected to the first connection electrode 13, a first insulating layer 18 is formed on a side of the first signal trace away from the initial substrate 100, the first insulating layer 18 is provided with a first via, and the first via exposes one end of the first signal trace 11 connected to the chip 14.

In some examples, the step S13 may include coating the blind hole 101 and the first surface of the initial substrate 100 with a first conductive thin film, i.e., forming a first seed layer, then performing an electroplating or electroless plating process on the first seed layer, so that the first seed layer is grown and thus becomes thick; forming a first connection electrode 13 in the blind hole 101, and then patterning (i.e., coating glue, exposing, developing, etching) the grown thick first seed layer on the first surface to form a pattern including the first signal trace 11; and finally, forming the first insulating layer 18 on a side of the first signal trace away from the initial substrate 100, and forming the first via extending through the first insulating layer 18, wherein the first via exposes one end of the first signal trace 11 connected to the chip 14.

At the step S14, a carrier substrate 200 is fixed on a side of the first signal trace 11 away from the first surface of the initial substrate 100.

In some examples, the carrier substrate 200 includes, but is not limited to, a carrier glass. In step S14, the carrier substrate 200 may be fixed on a side of the first signal trace 11 away from the first surface of the initial substrate 100 by a second adhesive layer 201. The second adhesive layer 201 includes, but is not limited to, a temperature-controlled adhesive. In the embodiment of the present disclosure, the carrier substrate 200 is attached to the initial substrate 100 by the temperature-controlled adhesive before the initial substrate 100 is thinned, so as to temporarily strengthen and protect the initial substrate 100.

In some examples, the step S14 further includes thinning the initial substrate 100 from a side of the second surface to form the dielectric substrate 10 and to expose the first connection electrode 13.

In some examples, the step S14 may include thinning the side where the second surface of the initial substrate 100 is located, followed by polishing through a CMP process to reduce roughness and expose the first connection electrode 13. That is, a through hole extending through the dielectric substrate 10 is formed in step S14.

At the step S15, the second signal trace 12 is formed on a side of the dielectric substrate 10 away from the first signal trace 11 such that one end of the second signal trace 12 is electrically connected to the first connection electrode 13, and a second insulating layer 19 is formed on a side of the second signal trace away from the dielectric substrate 10 such that the second insulating layer 19 is provided with a second via, and the second via exposes one end of the second signal trace 12 connected to the printed circuit board 20.

In some examples, the step S15 may include forming a second conductive film on a side of the dielectric substrate 10 away from the first signal trace 11, coating a photoresist on a side of the second conductive thin film away from the dielectric substrate 10, and then forming a pattern including the second signal trace 12 through exposure, development, and etching processes; and finally, forming a second insulating layer 19 on a side of the second signal trace away from the dielectric substrate 10, and forming a second via extending through the second insulating layer 19, wherein the second via exposes one end of the second signal trace 12 connected to the printed circuit board 20.

At the step S16, the carrier substrate 200 is removed, and an auxiliary substrate 300 is fixed on a side of the second signal trace 12 away from the dielectric substrate 10.

In some examples, the auxiliary substrate 300 serves as a reinforcing substrate, and may be a glass substrate plated with copper on both sides, or may be made of other materials such as stainless steel. Specifically, in the step S16, the auxiliary substrate 300 may be fixed to the side of the second signal trace 12 away from the dielectric substrate 10 by using the first adhesive layer 301. The first adhesive layer 301 includes, but is not limited to, a bonding adhesive, and the bonding adhesive may be specifically a temperature-controlled adhesive, such as a bonding adhesive for bonding at 200° C. and a temperature-controlled adhesive for debonding at 200° C.

In the embodiment of the present disclosure, the reinforcing substrate is fixed before the chip 14 is mounted, so that the strength of the dielectric substrate 10 can be effectively increased, and the risk of smashing can be reduced.

At the step S17, the chip 14 is mounted on a side of the first signal trace 11 away from the dielectric substrate 10, and an encapsulation layer 15 is formed on a side of the chip 14 away from the dielectric substrate 10, that is, encapsulating the chip 14.

In some examples, the first signal trace 11 and the chip 14 may be electrically connected together by soldering in step S17. For example: a first connection pad 16 is formed at one end of the first signal trace 11 connected to the chip 14, and then the first connection pad 16 and the chip 14 are connected together by soldering through a solder ball or a copper column, so as to electrically connect the first signal trace 11 and the chip 14. The first connection pad 16 may be made of electroless nickel immersion gold. The encapsulation layer 15 may be made of a molding compound.

At the step S18, the auxiliary substrate 300 is removed.

The encapsulation substrate is manufactured.

The second signal trace 12 is electrically connected to the printed circuit board 20 subsequently, and the second signal trace 12 and the printed circuit board 20 may be connected together by soldering. Therefore, the second connection pad 17 is formed at one end of the second signal trace 12 connected to the printed circuit board 20, and then the second connection pad 17 and the printed circuit board 20 are connected by soldering through a solder ball or a copper column, so as to electrically connect the second signal trace 12 and the printed circuit board 20. The second connection pad 17 may be made of electroless nickel immersion gold.

Correspondingly, the embodiment of the present disclosure further provides a method for manufacturing a functional substrate, including the steps of manufacturing the encapsulation substrate, and further includes a step of electrically connecting the second signal trace 12 to the printed circuit board 20 on the basis of manufacturing the encapsulation substrate.

In some examples, the second signal trace 12 and the printed circuit board 20 may be connected together by soldering. Therefore, the second connection pad 17 is formed at one end of the second signal trace 12 connected to the printed circuit board 20, and then the second connection pad 17 and the printed circuit board 20 are connected together by soldering through a solder ball or a copper column, so as to electrically connect the second signal trace 12 and the printed circuit board 20. The second connection pad 17 may be made of electroless nickel immersion gold.

In the first example, the carrier substrate 200 is attached to the initial substrate 100 by the temperature-controlled adhesive before the initial substrate 100 is thinned, so as to temporarily strengthen and protect the initial substrate 100; the reinforcing substrate is fixed before the chip 14 is mounted, so that the strength of the dielectric substrate 10 can be effectively increased, and the risk of smashing can be reduced.

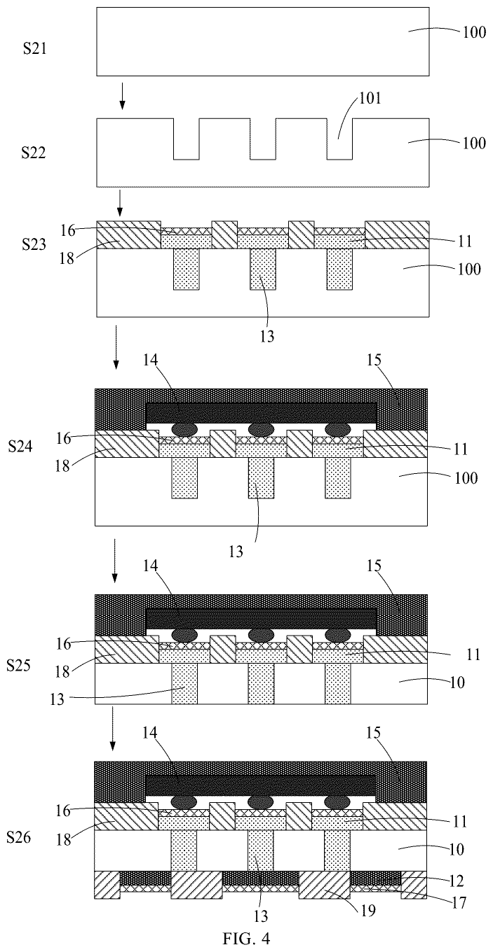

In a second example, FIG. 4 is a flowchart of a method of manufacturing an encapsulation substrate according to a second example of the embodiment of the present disclosure; as shown in FIG. 4, the first signal trace 11 in the encapsulation substrate is electrically connected to the chip 14, and the second signal trace 12 is electrically connected to the printed circuit board 20. The method for manufacturing an encapsulation substrate specifically includes the following steps S21 to S26.

At the step S21, an initial substrate 100 is provided, and the initial substrate 100 includes a first surface and a second surface which are oppositely arranged along a thickness direction of the initial substrate 100.

In some examples, the initial substrate 100 includes, but is not limited to, a glass substrate. In the embodiment of the present disclosure, as an example, the initial substrate 100 is the glass substrate. The glass substrate has low dielectric loss and thus, has a good application prospect in the field of high-frequency signal transmission.

At the step S22, the initial substrate 100 is processed to form a blind hole 101 extending through a part of the initial substrate 100 in the thickness direction of the initial substrate 100, and a first opening of the blind hole 101 extends through the first surface.

In some examples, the step S22 may include forming the blind hole 101 extending through a partial thickness of the initial substrate 100 through a mechanical process, a laser process, a chemical etching process, a laser modification process and the like in combination with a wet etching process.

At the step S23, a first connection electrode 13 is formed in the blind hole 101 and a first signal trace 11 is formed on the first surface of the initial substrate 100 such that one end of the first signal trace 11 is electrically connected to the first connection electrode 13, and a first insulating layer 18 is formed on a side of the first signal trace away from the initial substrate 100, the first insulating layer 18 is provided with a first via, and the first via exposes one end of the first signal trace 11 connected to the chip 14.

In some examples, the step S23 may include coating the blind hole 101 and the first surface of the initial substrate 100 with a first conductive thin film, i.e., forming a first seed layer, then performing an electroplating or electroless plating process on the first seed layer, so that the first seed layer is grown and thus becomes thick; forming a first connection electrode 13 in the blind hole 101, and then patterning (i.e., coating glue, exposing, developing, etching) the grown thick first seed layer on the first surface to form a pattern including the first signal trace 11; and finally, forming the first insulating layer 18 on a side of the first signal trace away from the initial substrate 100, and forming the first via extending through the first insulating layer 18, wherein the first via exposes one end of the first signal trace 11 connected to the chip 14.

At the step S24, the chip 14 is mounted on a side of the first signal trace 11 away from the initial substrate 100, and an encapsulation layer 15 is formed on a side of the chip 14 away from the dielectric substrate 10, that is, encapsulating the chip 14.

In some examples, the first signal trace 11 and the chip 14 may be electrically connected together by soldering in the step S24. For example: a first connection pad 16 is formed at one end of the first signal trace 11 connected to the chip 14, and then the first connection pad 16 and the chip 14 are connected together by soldering through a solder ball or a copper column, so as to electrically connect the first signal trace 11 and the chip 14. The first connection pad 16 may be made of electroless nickel immersion gold. The encapsulation layer 15 may be made of a molding compound.

At the step S25, the initial substrate 100 is thinned from a side of the second surface to form the dielectric substrate 10 and to expose the first connection electrode 13.

In some examples, the step S25 may include thinning the side where the second surface of the initial substrate 100 is located, followed by polishing through a CMP process to reduce roughness and expose the first connection electrode 13. That is, a through hole extending through the dielectric substrate 10 is formed in step S25.

At the step S26, the second signal trace 12 is formed on a side of the dielectric substrate 10 away from the first signal trace 11 such that one end of the second signal trace 12 is electrically connected to the first connection electrode 13, and a second insulating layer 19 is formed on a side of the second signal trace away from the dielectric substrate 10 such that the second insulating layer 19 is provided with a second via, and the second via exposes one end of the second signal trace 12 connected to the printed circuit board 20.

In some examples, the step S26 may include forming a second conductive film on a side of the dielectric substrate 10 away from the first signal trace 11, coating a photoresist on a side of the second conductive thin film away from the dielectric substrate 10, and then forming a pattern including the second signal trace 12 through exposure, development, and etching processes; and finally, forming a second insulating layer 19 on a side of the second signal trace away from the dielectric substrate 10, and forming a second via extending through the second insulating layer 19, wherein the second via exposes one end of the second signal trace 12 connected to the printed circuit board 20.

The encapsulation substrate is manufactured.

The second signal trace 12 is electrically connected to the printed circuit board 20 subsequently, and the second signal trace 12 and the printed circuit board 20 may be connected together by soldering. Therefore, the second connection pad 17 is formed at one end of the second signal trace 12 connected to the printed circuit board 20, and then the second connection pad 17 and the printed circuit board 20 are connected by soldering through a solder ball or a copper column, so as to electrically connect the second signal trace 12 and the printed circuit board 20. The second connection pad 17 may be made of electroless nickel immersion gold.

Correspondingly, the embodiment of the present disclosure further provides a method for manufacturing a functional substrate, including the steps of manufacturing the encapsulation substrate, and further includes a step of electrically connecting the second signal trace 12 to the printed circuit board 20 on the basis of manufacturing the encapsulation substrate.

In some examples, the second signal trace 12 and the printed circuit board 20 may be connected together by soldering. Therefore, the second connection pad 17 is formed at one end of the second signal trace 12 connected to the printed circuit board 20, and then the second connection pad 17 and the printed circuit board 20 are connected together by soldering through a solder ball or a copper column, so as to electrically connect the second signal trace 12 and the printed circuit board 20. The second connection pad 17 may be made of electroless nickel immersion gold.

In the second example, the encapsulated chip 14 is used as a reinforcing substrate, so that no additional reinforcing substrate is needed in the manufacturing method. In this way, the process is greatly simplified; and the mechanical strength of the molding compound is higher, which is more beneficial to the wafer-level processing in the whole process and effectively solves the problems of warping and the like.

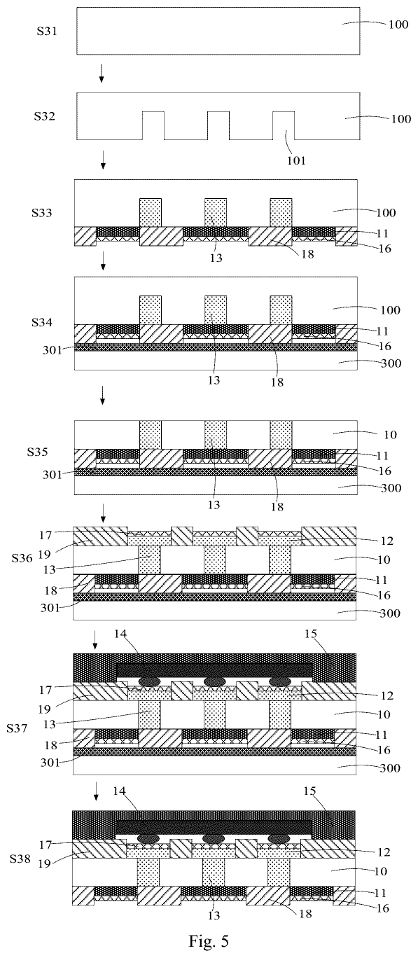

In a third example: FIG. 5 is a flowchart of a method of manufacturing an encapsulation substrate according to a third example of the embodiment of the present disclosure; as shown in FIG. 5, in the encapsulation substrate, the first signal trace 11 is electrically connected to the printed circuit board 20, and the second signal trace 12 is electrically connected to the chip 14. The method for manufacturing an encapsulation substrate specifically includes the following steps S31 to S38.

At the step S31, an initial substrate 100 is provided, and the initial substrate 100 includes a first surface and a second surface which are oppositely arranged along a thickness direction of the initial substrate 100.

In some examples, the initial substrate 100 includes, but is not limited to, a glass substrate. In the embodiment of the present disclosure, as an example, the initial substrate 100 is the glass substrate. The glass substrate has low dielectric loss and thus, has a good application prospect in the field of high-frequency signal transmission.

At the step S32, the initial substrate 100 is processed to form a blind hole 101 extending through a part of the initial substrate 100 in the thickness direction of the initial substrate 100, and a first opening of the blind hole 101 extends through the first surface.

In some examples, the step S32 may include forming the blind hole 101 extending through a partial thickness of the initial substrate 100 through a mechanical process, a laser process, a chemical etching process, a laser modification process and the like in combination with a wet etching process.

At the step S33, a first connection electrode 13 is formed in the blind hole 101, and a first signal trace 11 is formed on the first surface of the initial substrate 100 such that one end of the first signal trace 11 is electrically connected to the first connection electrode 13, and a first insulating layer 18 is formed on a side of the first signal trace away from the initial substrate 100, the first insulating layer 18 is provided with a first via, and the first via exposes one end of the first signal trace 11 connected to the printed circuit board 20.

In some examples, the step S33 may include coating the blind hole 101 and the first surface of the initial substrate 100 with a first conductive thin film, i.e., forming a first seed layer, then performing an electroplating or electroless plating process on the first seed layer, so that the first seed layer is grown and thus becomes thick; forming a first connection electrode 13 in the blind hole 101, and then patterning (i.e., coating glue, exposing, developing, etching) the grown thick first seed layer on the first surface to form a pattern including the first signal trace 11; and finally, forming the first insulating layer 18 on a side of the first signal trace away from the initial substrate 100, and forming the first via extending through the first insulating layer 18, wherein the first via exposes one end of the first signal trace 11 connected to the printed circuit board 20.

At the step S34, an auxiliary substrate 300 is fixed on a side of the first signal trace 11 away from the dielectric substrate 10.

In some examples, the auxiliary substrate 300 serves as a reinforcing substrate, and may be a glass substrate plated with copper on both sides, or may be made of other materials such as stainless steel. Specifically, in the step S34, the auxiliary substrate 300 may be fixed to the side of the first signal trace 11 away from the dielectric substrate 10 by using the first adhesive layer 301. The first adhesive layer 301 includes, but is not limited to, a bonding adhesive, and the bonding adhesive may be specifically a temperature-controlled adhesive, such as a bonding adhesive for bonding at 200° C. and a temperature-controlled adhesive for debonding at 200° C.

In the embodiment of the present disclosure, the reinforcing substrate is fixed before the chip 14 is mounted, so that the strength of the dielectric substrate 10 can be effectively increased, and the risk of smashing can be reduced.

At the step S35, from a side of the second surface, the initial substrate 100 is thinned to form the dielectric substrate 10 and expose the first connection electrode 13.

In some examples, the step S35 may include thinning the side where the second surface of the initial substrate 100 is located, followed by polishing through a CMP process to reduce roughness and expose the first connection electrode 13. That is, a through hole extending through the dielectric substrate 10 is formed in the step S35.

At the step S36, a second signal trace 12 is formed on a side of the dielectric substrate 10 away from the first signal trace 11 such that one end of the second signal trace 12 is electrically connected to the first connection electrode 13, and a second insulating layer 19 is formed on a side of the second signal trace away from the dielectric substrate 10 such that the second insulating layer 19 is provided with a second via, and the second via exposes one end of the second signal trace 12 connected to the chip 14.

In some examples, the step S36 may include forming a second conductive film on a side of the dielectric substrate 10 away from the first signal trace 11, coating a photoresist on a side of the second conductive thin film away from the dielectric substrate 10, and then forming a pattern including the second signal trace 12 through exposure, development, and etching processes; and finally, forming a second insulating layer 19 on a side of the second signal trace away from the dielectric substrate 10, and forming a second via extending through the second insulating layer 19, wherein the second via exposes one end of the second signal trace 12 connected to the chip 14.

At the step S37, the chip 14 is mounted on a side of the second signal trace 12 away from the dielectric substrate 10, and an encapsulation layer 15 is formed on a side of the chip 14 away from the dielectric substrate 10, that is, encapsulating the chip 14.

In some examples, the second signal trace 12 and the chip 14 may be electrically connected together by soldering in the step S37. For example, a second connection pad 17 is formed at one end of the second signal trace 12 connected to the chip 14, and then the second connection pad 17 and the chip 14 are connected together by soldering through a solder ball or a copper column, so as to electrically connect the second signal trace 12 and the chip 14. The second connection pad 17 may be made of electroless nickel immersion gold. The encapsulation layer 15 may be made of a molding compound.

At the step S38, the auxiliary substrate 300 is removed.

The encapsulation substrate is manufactured.

The first signal trace 11 is electrically connected to the printed circuit board 20 subsequently, and the first signal trace 11 and the printed circuit board 20 may be connected together by soldering. Therefore, the first connection pad 16 is formed at one end of the first signal trace 11 connected to the printed circuit board 20, and then the first connection pad 16 and the printed circuit board 20 are connected by soldering through a solder ball or a copper column, so as to electrically connect the first signal trace 11 and the printed circuit board 20. The first connection pad 16 may be made of electroless nickel immersion gold.

Correspondingly, the embodiment of the present disclosure further provides a method for manufacturing a functional substrate, including the steps of manufacturing the encapsulation substrate, and further includes a step of electrically connecting the first signal trace 11 to the printed circuit board 20 on the basis of manufacturing the encapsulation substrate.

In some examples, the first signal trace 11 and the printed circuit board 20 may be connected together by soldering. Therefore, the first connection pad 16 is formed at one end of the first signal trace 11 connected to the printed circuit board 20, and then the first connection pad 16 and the printed circuit board 20 are connected together by soldering through a solder ball or a copper column, so as to electrically connect the first signal trace 11 and the printed circuit board 20. The first connection pad 16 may be made of electroless nickel immersion gold.

In the third example, it is necessary to provide the reinforcing substrate only once in the manufacturing method, and the reinforcing substrate can temporarily strengthen and protect the initial substrate 100 in the thinning process and can play a role in reinforcement in the process of encapsulating the chip 14.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A method for manufacturing an encapsulation substrate, comprising:
providing an initial substrate, wherein the initial substrate comprises a first surface and a second surface which are oppositely arranged along a thickness direction of the initial substrate, and the initial substrate comprises a glass substrate;
processing the initial substrate to form a blind hole extending through a part of the initial substrate in the thickness direction of the initial substrate, wherein a first opening of the blind hole extends through the first surface;
forming a first connection electrode in the blind hole, and forming a first signal trace on the first surface, wherein one end of the first signal trace is electrically connected to the first connection electrode;
thinning the initial substrate from a side of the second surface to form a dielectric substrate comprising a through hole and to expose the first connection electrode; and
forming a second signal trace on a side of the dielectric substrate away from the first signal trace, wherein one of the first signal trace and the second signal trace is configured to be electrically connected to a chip, and the other one is configured to be electrically connected to a printed circuit board.

2. The method according to claim 1, wherein the thinning the initial substrate from the side of the second surface to form the dielectric substrate comprising the through hole and to expose the first connection electrode comprises:
fixing a carrier substrate on a side of the first signal trace away from the first surface; and
thinning the initial substrate from the side of the second surface to form the dielectric substrate comprising the through hole and to expose the first connection electrode; and
before the forming the second signal trace on the side of the dielectric substrate away from the first signal trace, the method further comprises: removing the carrier substrate.

3. The method according to claim 2, wherein after the forming the second signal trace on the side of the dielectric substrate away from the first signal trace, the method further comprises:
fixing an auxiliary substrate on a side of the second signal trace away from the dielectric substrate;
mounting the chip on a side of the first signal trace away from the dielectric substrate, wherein the chip is electrically connected to the first signal trace;
forming an encapsulation layer on a side of the chip away from the dielectric substrate; and
removing the auxiliary substrate.

4. The method according to claim 3, wherein the chip is electrically connected to the first signal trace by soldering.

5. The method according to claim 3, wherein the auxiliary substrate is fixed to the side of the second signal trace away from the dielectric substrate through a first adhesive layer.

6. The method according to claim 2, wherein the carrier substrate is fixed to the side of the first signal trace away from the first surface through a second adhesive layer.

7. The method according to claim 1, wherein before the thinning the initial substrate from the side of the second surface to form the dielectric substrate comprising the through hole and to expose the first connection electrode, the method further comprises:
mounting the chip on a side of the first signal trace away from the first surface, wherein the chip is electrically connected to the first signal trace.

8. The method according to claim 1, wherein before the thinning the initial substrate from the side of the second surface to form the dielectric substrate comprising the through hole and to expose the first connection electrode, the method further comprises:
fixing an auxiliary substrate on a side of the first signal trace away from the first surface; and
thinning the initial substrate from the side of the second surface to form the dielectric substrate comprising the through hole and to expose the first connection electrode;
after the forming the second signal trace on the side of the dielectric substrate away from the first signal trace, the method further comprises:
mounting the chip on a side of the second signal trace away from the dielectric substrate, wherein the chip is electrically connected to the second signal trace; and
removing the auxiliary substrate.

9. The method according to claim 1, wherein the auxiliary substrate is fixed to a side of the first signal trace away from the first surface through a first adhesive layer.

10. The method according to claim 1, wherein one end of the first signal trace is connected to the first connection electrode, and a first connection pad is formed on a side of the other end of the first signal trace away from the dielectric substrate; and
one end of the second signal trace is connected to the first connection electrode, and a second connection pad is formed on a side of the other end of the second signal trace away from the dielectric substrate.

11. The method according to claim 1, wherein the first connection electrode is formed through an electroplating process or an electroless plating process.

12. An encapsulation substrate, comprising:
a dielectric substrate, comprising a through hole extending through the dielectric substrate in a thickness direction of the dielectric substrate; wherein the dielectric substrate is a glass substrate;
a first connection electrode in the through hole; and
a first signal trace and a second signal trace respectively on two opposite surfaces of the dielectric substrate and electrically connected to each other through the first connection electrode;
wherein one of the first signal trace and the second signal trace is configured to be electrically connected to a chip, and the other one is configured to be electrically connected to a printed circuit board.

13. The encapsulation substrate according to claim 12, further comprising a chip electrically connected to the first signal trace, and an encapsulation layer on a side of the chip away from the dielectric substrate.

14. The encapsulation substrate according to claim 12, wherein one end of the first signal trace is electrically connected to the first connection electrode, and the other end of the first signal trace is electrically connected to a first connection pad on a side of the first signal trace away from the dielectric substrate.

15. The encapsulation substrate according to claim 12, wherein one end of the second signal trace is electrically connected to the first connection electrode, and the other end of the second signal trace is electrically connected to a second connection pad on a side of the second signal trace away from the dielectric substrate.

16. A method for manufacturing a functional substrate, comprising manufacturing an encapsulation substrate, which comprises:
providing an initial substrate, wherein the initial substrate comprises a first surface and a second surface which are oppositely arranged along a thickness direction of the initial substrate, and the initial substrate comprises a glass substrate;
processing the initial substrate to form a blind hole extending through a part of the initial substrate in the thickness direction of the initial substrate, wherein a first opening of the blind hole extends through the first surface;
forming a first connection electrode in the blind hole, and forming a first signal trace on the first surface, wherein one end of the first signal trace is electrically connected to the first connection electrode;
thinning the initial substrate from a side of the second surface to form a dielectric substrate comprising a through hole and to expose the first connection electrode; and
forming a second signal trace on a side of the dielectric substrate away from the first signal trace, wherein one of the first signal trace and the second signal trace is configured to be electrically connected to a chip, and the other one is configured to be electrically connected to a printed circuit board.

17. The method according to claim 16, wherein the first signal trace is electrically connected to the chip, the method further comprises: electrically connecting the second signal trace with the printed circuit board; or the second signal trace is electrically connected to the chip, the method further comprises: electrically connecting the first signal trace with the printed circuit board.

18. The method according to claim 17, wherein the electrically connecting the second signal trace with the printed circuit board comprises:
electrically connecting the second signal trace with the printed circuit board by soldering.

19. The method according to claim 17, wherein the electrically connecting the first signal trace with the printed circuit board comprises:
electrically connecting the first signal trace with the printed circuit board by soldering.

20. A functional substrate, comprising the encapsulation substrate according to claim 12; wherein one of the first signal trace and the second signal trace is electrically connected to the chip, and the other one is electrically connected to the printed circuit board.
